(19) United States
(12) Patent Application Publication
(10) Pub. No.: US 2024/0363161 A1
(43) Pub. Date: Oct. 31, 2024

(54) ELECTRONIC DEVICE AND METHOD FOR OPERATING THE SAME

(71) Applicant: MACRONIX INTERNATIONAL CO., LTD., Hsinchu (TW)

(72) Inventors: Cheng-Lin SUNG, Hsinchu County (TW); Hsiang-Lan LUNG, Kaohsiung City (TW)

(21) Appl. No.: 18/139,410

(22) Filed: Apr. 26, 2023

(51) Int. Cl. G11C 13/00; G11C 7/10

(52) U.S. Cl. CPC G11C 13/0097; G11C 7/1006; G11C 13/004

(57) ABSTRACT

An electronic device is provided. The electronic device comprises a computational memory. The computational memory comprises a first memory array and a second memory array. The first memory array and the second memory array contain same data. The first memory array and the second memory array are configured to perform operations in an out of phase manner.

### TECHNICAL FIELD

This disclosure relates to an electronic device and a method for operating the same. More particularly, this disclosure relates to an electronic device comprising a computational memory and a method for operating the same.

### BACKGROUND

With the rapid development of artificial intelligence (AI) algorithm in various fields of applications such as automobile, consumer, military market, and so on, the computing performance is no longer dominated solely by optimizing AI software, but the natural bottleneck of hardware accelerators should be overcome. In a typical AI computation, huge amount of data is stored in a memory in standby mode and transferred to a CPU during computation. The large movement causes data congestion and reduces the computing performance. As such, hardware infrastructure for accelerating AI computation is eagerly to be improved. To optimize data traffic between a memory bus and a processing unit, in-memory computing is a promising alternative. However, current memories have some drawbacks, including read disturb, retention loss, drift, and endurance issues. In order to prevent degrade of AI inference operation, data loss should be avoided. Data refresh is typical technical means to compensate data loss, and should be done before inference accuracy degrades. However, the insertion of refresh operation between basic operations of AI algorithm may lead to additional time consumption and reduce the computing performance for AI inference operation. For example, it takes almost 20 seconds to refresh the 19 layers of weights in a VGG19 architecture.

### SUMMARY

This disclosure provides an electronic device and a method for operating the same to address the time consuming and computing performance reducing issues.

In one aspect of the disclosure, an electronic device is provided. The electronic device comprises a computational memory. The computational memory comprises a first memory array and a second memory array. The first memory array and the second memory array contain same data. The first memory array and the second memory array are configured to perform operations in an out of phase manner.

In another aspect of the disclosure, a method for operating an electronic device is provided. The electronic device comprises a computational memory. The computational memory comprises a first memory array and a second memory array. The method comprises following steps. First, same data is stored into the first memory array and the second memory array. Thereafter, operations are performed in the first memory array and the second memory array in an out of phase manner.

### BRIEF DESCRIPTION OF THE DRAWINGS

FIGS. 1-2 illustrate an electronic device according to the disclosure.

FIG. 3-4 illustrate a method for operating an electronic device according to the disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The description and the drawings are provided for illustrative only, and not intended to result in a limitation. For clarity, the elements may not be drawn to scale. In addition, some elements and/or reference numerals may be omitted from some drawings. It is contemplated that the elements and features of one embodiment can be beneficially incorporated in another embodiment without further recitation.

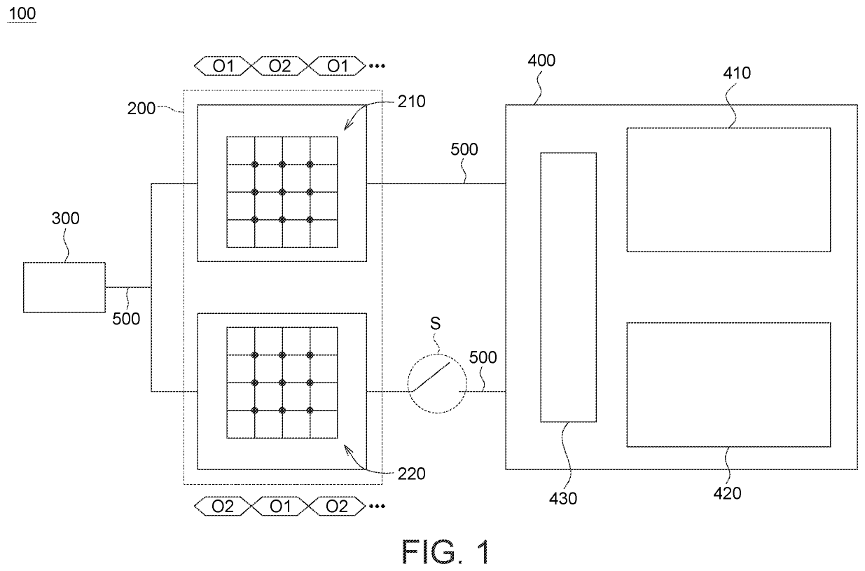

Referring to FIG. 1, an electronic device 100 according to the disclosure is shown. The electronic device 100 comprises a computational memory 200. The computational memory 200 comprises a first memory array 210 and a second memory array 220. The first memory array 210 and the second memory array 220 contain same data. The first memory array 210 and the second memory array 220 are configured to perform operations in an out of phase manner.

More specifically, the second memory array 220 can be a duplicated array of the first memory array 210. In other words, data stored in the second memory array 220 can be exactly the same as data stored in the first memory array 210. It can be achieved by storing the same data into both the first memory array 210 and the second memory array 220 and verifying. However, the term “duplicated array” used in the disclosure still allows for temporary short-time differences between the two arrays in some particular conditions, such as rewriting data into one of the arrays to ensure data accuracy. The data can be weight data for an algorithm, but the disclosure is not limited thereto. Memory cells of the first memory array 210 and the second memory array 220 are represented by solid dots on cross points in the accompanying drawings.

According to some embodiments, the first memory array 210 is configured to alternately perform first operations O1 and second operations O2, and the second memory array 220 is configured to alternately perform the second operations O2 and the first operations O1. When the first memory array 210 performs the first operations O1, the second memory array 220 performs the second operations O2. When the first memory array 210 performs the second operations O2, the second memory array 220 performs the first operations O1. For example, the first operations O1 can be read operations, and the second operations O2 can be refresh operations. When the first memory array 210 performs the read operations, the second memory array 220 performs the refresh operations. A refresh operation can comprise reading out data from a memory array and rewriting the read data into the memory array. When the first memory array 210 performs the refresh operations, the second memory array 220 performs the read operations. In such conditions, there is always one of the first memory array 210 or the second memory array 220 performs a read operation, and the other one can perform a refresh operation at the same time. As such, more accurate data, such as weight data for an algorithm, can be obtained without wasting time.

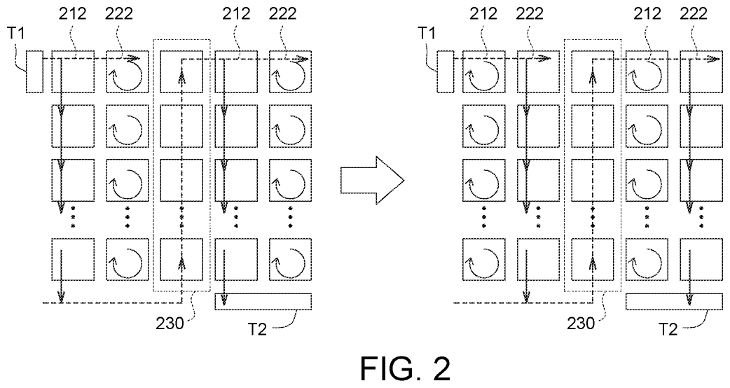

Referring to FIG. 2, further details of the computational memory 200 is shown. In some embodiments, the first memory array 210 comprises a plurality of first sub-arrays 212, and the second memory array 220 comprises a plurality of second sub-arrays 222. The first sub-arrays 212 and the second sub-arrays 222 can be arranged into a plurality of sub-array pairs, and each sub-array pair comprises a first sub-array 212 and a second sub-array 222 adjacent to the first sub-array 212. The sub-array pairs can further arranged in layers. However, it is understood that the first memory array 210 and the second memory array 220 can be arranged in other manner. For example, the first memory array 210 and the second memory array 220 can be arranged as individual integral bodies, as shown in FIG. 1.

As shown in FIG. 2, the computational memory 200 can further comprise one or more fault tolerance layers 230 each arranged between two adjacent layers of the sub-array pairs. The fault tolerance layer 230 can provide tolerance to variation between the sub-array pairs. When several fault tolerance layers 230 are needed, they can be arranged as a layer of sub-arrays to save cost of the memory.

In FIG. 2, straight arrows indicate directions of data flow from an input terminal T1 to an output terminal T2, solid downward arrows represent the read operations, and the curved arrows represent the refresh operation. As shown in the left part of FIG. 2, when the first sub-arrays 212 perform a read operation, the second sub-arrays 222 perform a refresh operation. Then, the first sub-arrays 212 perform a refresh operation, and the second sub-arrays 222 perform a read operation, as shown in the right part of FIG. 2.

Referring back to FIG. 1, according to some embodiments, the computational memory 200 can be a nonvolatile memory, such as a phase change memory (PCM), a resistive random access memory (ReRAM), a ferroelectric random access memory (FeRAM), a ferroelectric field effect transistor (FeFET) memory, a magnetoresistive random access memory (MRAM), a flash memory, or the like.

The electronic device 100 can further comprise a memory controller 300. The memory controller 300 is coupled to the computational memory 200. The memory controller 300 is configured to control sequences of the first operations O1 and the second operations O2 for the first memory array 210 and the second memory array 220. Specifically, the memory controller 300 can transmit command sequences for the first operations O1 and the second operations O2 to the first memory array 210 and the second memory array 220. During computation, the command alternates the first operations O1 and the second operations O2 sequentially. An out of phase alternative pattern with respect to a pattern to the first memory array 210 is provided to the second memory array 220.

The electronic device 100 can further comprise a processor 400. The processor 400 is coupled to the computational memory 200. The processor 400 is in communication with only one of the first memory array 210 or the second memory array 220 that performs the first operations O1. For example, in conditions that the first operations O1 are read operations and the second operations O2 are refresh operations, the processor 400 can always read one of the first memory array 210 or the second memory array 220 that performs the read operations. In some embodiments, the processor 400 comprises a control unit 410, an arithmetic logic unit (ALU) 420, and a cache 430, but the disclosure is not limited thereto.

The electronic device 100 can further comprise a plurality of signal lines 500 for connections between the computational memory 200 and the memory controller 300 and between the computational memory 200 and the processor 400. For example, the signal lines 500 between the computational memory 200 and the processor 400 can be bit lines and/or source lines, but the disclosure is not limited thereto. According to some embodiments, switches S can be arranged on the signal lines 500 between the computational memory 200 and the processor 400 to connect a communication path between one of the first memory array 210 or the second memory array 220 that performs the first operations O1 and the processor 400, and cut off a communication path between the other one and the processor 400.

Now the disclosure is directed to a method for operating an electronic device. The electronic device comprises a computational memory. The computational memory comprises a first memory array and a second memory array. The second memory array can be a duplicated array of the first memory array. The electronic device to be operated can be, for example, the electronic device 100 as described above, and other details for the electronic device will not be repeated herein. For clarity, the details of the method will be described hereinafter with reference to the electronic device 100.

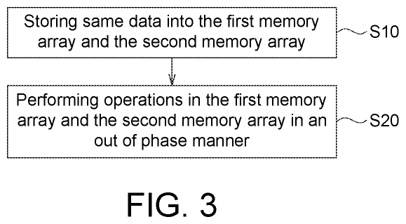

Referring to FIG. 3, a flow diagram of the method according to the disclosure is shown. In a step S10, same data is stored into the first memory array 210 and the second memory array 220. The data can be, for example, weight data for an algorithm.

In a step S20, operations are performed in the first memory array 210 and the second memory array 220 in an out of phase manner. More specifically, the method can comprise alternately performing first operations O1 and second operations O2 in the first memory array 210 and alternately performing the second operations O2 and the first operations O1 in the second memory array 220. When the first operations O1 are performed in the first memory array 210, the second operations O2 are performed in the second memory array 220. When the second operations O2 are performed in the first memory array 210, the first operations O1 are performed in the second memory array 220, as shown in FIG. 1.

The first operations O1 can be read operations, and the second operations O2 can be refresh operations. Accordingly, in some embodiments, the method can further comprise transmitting command sequences for the read operations and the refresh operations from a memory controller 300 of the electronic device 100 to the first memory array 210 and the second memory array 220. In some embodiments, the method can further comprise always reading one of the first memory array 210 or the second memory array 220 that performs the read operations through a processor 400 of the electronic device 100. In such conditions, the processor 400 and thus an user can see a computational memory 200 that always perform required read operations, without wasting time on refresh operations to ensure data accuracy.

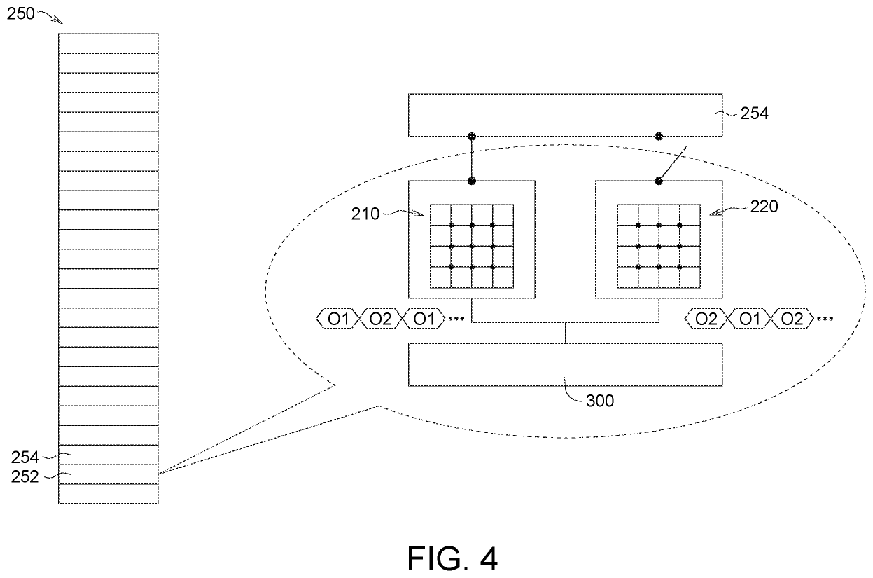

Referring to FIG. 4, an AI architecture 250 for the computational memory 200 is shown. The AI architecture 250 can be VGG16 architecture, VGG19 architecture, or the like. The AI architecture 250 comprises several layers, including a layer 252 and its next layer 254. According to some embodiments, the first memory array 210 can comprise a plurality of first sub-arrays 212 for different layers of the AI architecture 250. Similarly, the second memory array 220 can comprise a plurality of second sub-arrays 222 for different layers of the AI architecture 250. Accordingly, the method can further comprise transmitting data from the first sub-arrays 212 and the second sub-arrays 222 belonging to a layer in the AI architecture 250 to a next layer in the AI architecture 250, wherein the next layer receives the data from only ones of the first sub-arrays 212 or the second sub-arrays 222 belonging to the layer that perform the first operations O1. For example, the layer 254 can read data from only ones of the first sub-arrays 212 or the second sub-arrays 222 belonging to the layer 252 (represented by integral bodies of the first memory array 210 and the second memory array 220, respectively, in FIG. 4) that perform the read operations.

In summary, the disclosure provides an electronic device and a method for operating the same. In the disclosure, with the duplicated array, required operations from an user can be consecutively performed without wasting time on refresh operations to ensure data accuracy since when one of the first memory array or the second memory array performs the required operations, the other one can perform the refresh operations. As such, the time consuming and computing performance reducing issues caused by the data refresh can be mitigated while the data accuracy can be ensured. The hardware computation is accelerated. For an AI algorithm, the inference performance can be improved.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. An electronic device, comprising:
a computational memory comprising:
a first memory array; and
a second memory array;
wherein the first memory array and the second memory array contain same data; and
wherein the first memory array and the second memory array are configured to perform operations in an out of phase manner.

2. The electronic device according to claim 1, wherein the second memory array is a duplicated array of the first memory array.

3. The electronic device according to claim 1, wherein the first memory array is configured to alternately perform first operations and second operations, the second memory array is configured to alternately perform the second operations and the first operations, when the first memory array performs the first operations, the second memory array performs the second operations, and when the first memory array performs the second operations, the second memory array performs the first operations.

4. The electronic device according to claim 3, wherein the first operations are read operations, and the second operations are refresh operations.

5. The electronic device according to claim 3, further comprising:
a memory controller coupled to the computational memory, the memory controller configured to control sequences of the first operations and the second operations for the first memory array and the second memory array.

6. The electronic device according to claim 5, wherein the memory controller transmit command sequences for the first operations and the second operations to the first memory array and the second memory array.

7. The electronic device according to claim 3, further comprising:
a processor coupled to the computational memory, the processor in communication with only one of the first memory array or the second memory array that performs the first operations.

8. The electronic device according to claim 7, wherein the first operations are read operations, and the second operations are refresh operations, and the processor always reads one of the first memory array or the second memory array that performs the read operations.

9. The electronic device according to claim 1, wherein the first memory array comprises a plurality of first sub-arrays, the second memory array comprises a plurality of second sub-arrays, the first sub-arrays and the second sub-arrays are arranged into a plurality of sub-array pairs, and each sub-array pair comprises a first sub-array and a second sub-array adjacent to the first sub-array.

10. The electronic device according to claim 9, wherein the sub-array pairs are arranged in layers.

11. The electronic device according to claim 10, wherein the computational memory further comprises:
one or more fault tolerance layers each arranged between two adjacent layers of the sub-array pairs.

12. The electronic device according to claim 1, wherein the data is weight data for an algorithm.

13. A method for operating an electronic device, wherein the electronic device comprises a computational memory, and the computational memory comprises a first memory array and a second memory array, and wherein the method comprises:
storing same data into the first memory array and the second memory array; and
performing operations in the first memory array and the second memory array in an out of phase manner.

14. The method according to claim 13, wherein the second memory array is a duplicated array of the first memory array.

15. The method according to claim 13, comprising:
alternately performing first operations and second operations in the first memory array; and
alternately performing the second operations and the first operations in the second memory array;
wherein when the first operations are performed in the first memory array, the second operations are performed in the second memory array, and when the second operations are performed in the first memory array, the first operations are performed in the second memory array.

16. The method according to claim 15, wherein the first operations are read operations, and the second operations are refresh operations.

17. The method according to claim 16, further comprising:
transmitting command sequences for the read operations and the refresh operations from a memory controller of the electronic device to the first memory array and the second memory array.

18. The method according to claim 16, further comprising:
always reading one of the first memory array or the second memory array that performs the read operations through a processor of the electronic device.

19. The method according to claim 13, wherein the first memory array comprises a plurality of first sub-arrays, and the second memory array comprises a plurality of second sub-arrays, and wherein the method further comprises:
transmitting data from the first sub-arrays and the second sub-arrays belonging to a layer in an AI architecture to a next layer in the AI architecture, wherein the next layer receives the data from only ones of the first sub-arrays or the second sub-arrays belonging to the layer that perform the first operations.

20. The method according to claim 13, wherein the data is weight data for an algorithm.
